(19) United States
(12) Patent Application Publication
(10) Pub. No.: US 2026/0282847 A1
(43) Pub. Date: Sep. 17, 2026

(54) STACKED DIE MEMORY SPARING DEVICE AND METHOD

(71) Applicant: Micron Technology, Inc., Boise, ID (US)

(72) Inventors: Sai Krishna Mylavarapu, Folsom, CA (US); Todd A. Marquart, Boise, ID (US)

(21) Appl. No.: 19/566,252

(22) Filed: Mar. 13, 2026

Related U.S. Application Data
(60) Provisional application No. 63/771,404, filed on Mar. 13, 2025.

(51) Int. Cl. H10P 74/00; G11C 29/00; H10B 80/00; H10D 80/30; H10P 54/40; H10P 58/00; H10W 80/00; H10W 90/00; H10W 90/26

(52) U.S. Cl. CPC H10P 74/238; G11C 29/814; H10B 80/00; H10D 80/30; H10P 54/40; H10P 58/00; H10W 80/163; H10W 90/26; H10W 90/792

(57) ABSTRACT

Apparatus and methods are disclosed, including transistors, semiconductor devices and systems. Example methods include determining wafer level maps by mapping a defect distribution across multiple wafers. Example methods further include aligning wafers based on the wafer level maps to improve yield within die stacks. Example semiconductor devices and methods further include a controller circuit to allocate at least one memory die sub-portion.

### PRIORITY APPLICATION

This application claims the benefit of priority to U.S. Provisional Application Ser. No. 63/771,404, filed Mar. 13, 2025, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to transistor structures in complementary metal oxide semiconductor (CMOS) devices and manufacture.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2 illustrates a semiconductor wafer in accordance with some example embodiments.

FIG. 3A illustrates a semiconductor wafer stack in accordance with some example embodiments.

FIG. 3B illustrates a die stack in accordance with some example embodiments.

FIG. 4 illustrates multiple semiconductor wafers in accordance with some example embodiments.

FIG. 5 illustrates a stacked combination of multiple semiconductor wafers from FIG. 4 in accordance with some example embodiments.

FIG. 6 illustrates another stacked combination of multiple semiconductor wafers from FIG. 4 in accordance with some example embodiments.

FIG. 7 illustrates a semiconductor die stack in accordance with some example embodiments.

FIG. 8 illustrates a block diagram of a semiconductor die stack in accordance with some example embodiments.

FIG. 9 illustrates a flow diagram of a method o manufacture in accordance with some example embodiments.

FIG. 10 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

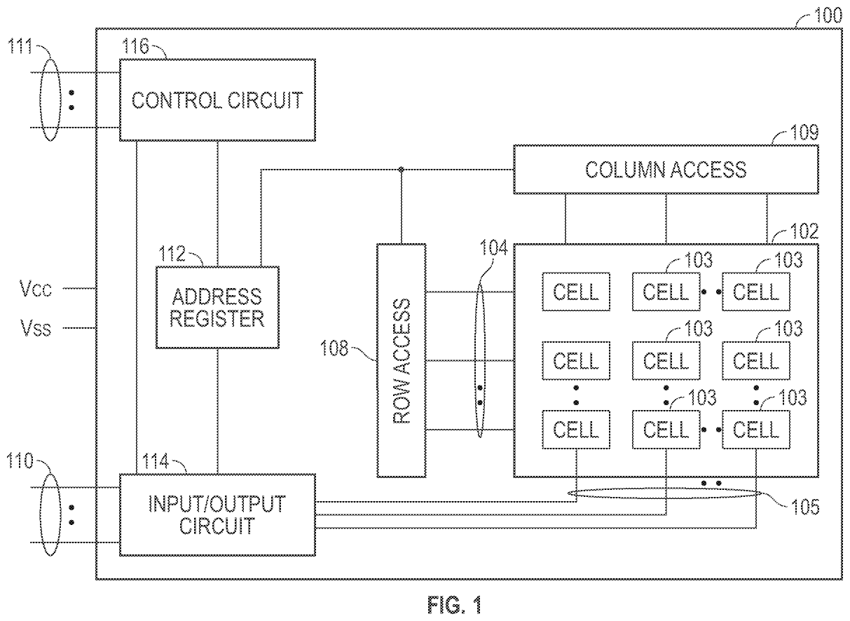

FIG. 1 shows a block diagram of an apparatus in the form of a memory device 100, according to an embodiment of the invention. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103. In one example, memory arrays 102 include NAND storage.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device). Memory device 100 can include a volatile memory device, such as a dynamic random access memory (DRAM) device.

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100.

One of ordinary skill in the art will recognize that memory device 100 may include other elements, several of which are not shown in FIG. 1, so as not to obscure the example embodiments described herein.

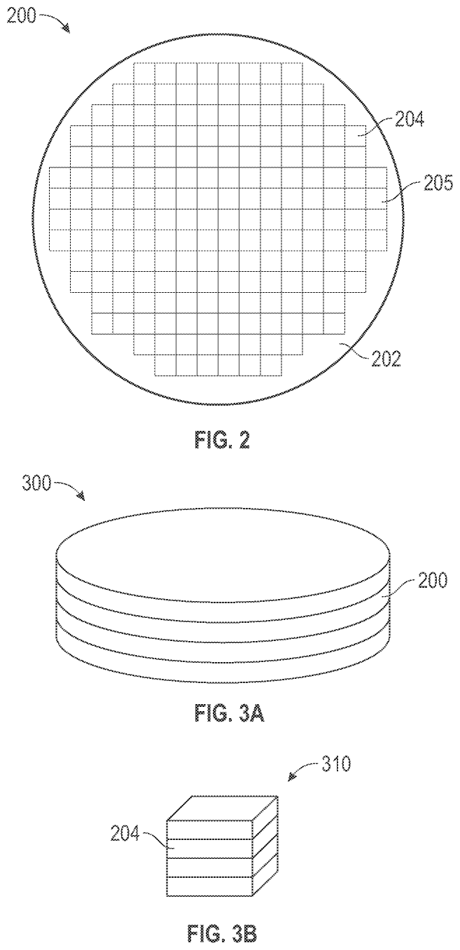

FIG. 2 shows a semiconductor wafer 200. In one example, the semiconductor wafer 200 includes single crystal silicon, although other semiconductor materials are also within the scope of the present disclosure. The semiconductor wafer 200 includes a plurality of individual semiconductor dies 204 that are formed in a bulk semiconductor substrate 202. In manufacture, a number of processing operations are performed at the wafer level, to make the plurality of individual semiconductor dies 204 side by side on a given semiconductor wafer 200. Wafer level processing operations include, but are not limited to optical lithography, ion implantation, chemical or physical deposition, etching, etc. After formation of the plurality of individual semiconductor dies 204, the dies 204 may be separated along lines 205 by sawing, or other means. It is desirable to form semiconductor devices at a wafer level, because more dies 204 are processed in a single given procedure when processing an entire wafer 200.

FIG. 3A shows a stack 300 of individual wafers 200. A number of semiconductor devices, such as memory devices, artificial intelligence (AI) devices, etc. utilize stacks of dies 204 to provide increased memory storage, processing, and functionality. In one method of manufacture, wafers 200 are stacked and the stacks of wafers 200 are later cut along lines, such as lines 205 from FIG. 2, to divide the wafer stack 300 into a number of coupled die stacks 310, composed of multiple dies 204 from the stack 300 of wafers 200. An example die stack 310 is shown in FIG. 3B.

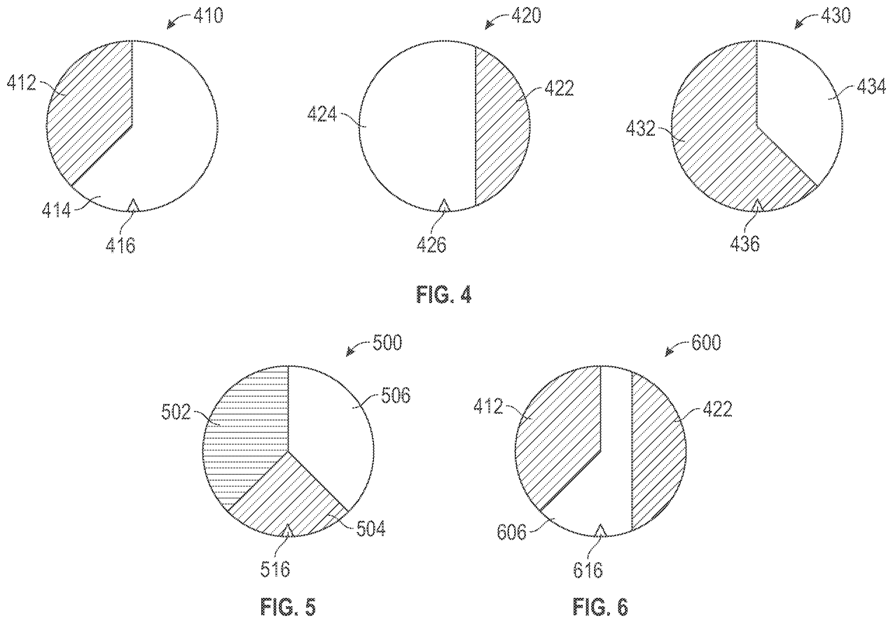

When a wafer 200 is formed, it often include one or more dies or regions within the wafer 200 that are defective in one way or another. When such wafers are stacked as in FIG. 3, the chances of having a defective die 204 within a die stack 310 are high, because the locations of defective dies 204 within a surface area of a given wafer 200 are random. FIGS. 4-6 illustrate an example method of manufacture to address this, and other concerns.

FIG. 4 shows three example wafers. A first wafer 410, a second wafer 420 and a third wafer 430 are shown. The first wafer 410 includes a functional die region 412 and a defective die region 414. An alignment feature 416 is included in the first wafer 410 to provide a reference for stacking wafers on top of one another in alignment, so that the dies within the wafers connect to one another properly.

The second wafer 420 includes a functional die region 422 and a defective die region 424. An alignment feature 426 is included in the second wafer 420. The third wafer 430 includes a functional die region 432 and a defective die region 434. An alignment feature 436 is included in the third wafer 430. It should be noted that functional region and defective region sizes shown are for illustration purposes only, and may not be drawn to scale.

In FIG. 5, the first wafer 410 is stacked with the third wafer 430. A functional overlap region 502 is shown where functional die regions 412 and 432 overlap. A partial functional overlap region 504 is also shown. The partial functional overlap region 504 includes a portion of the functional die region 432 from the third wafer 430 that overlaps a part of defective region 414 from the first wafer. A defective overlap region 506 is further shown where defective regions 414 and 434 overlap. It is desirable to maximize functional overlap region 502 in a stacked wafer arrangement.

In FIG. 6, the first wafer 410 is stacked with the second wafer 420. In the stacking of FIG. 6, there is no overlap between functional die region 412 and functional die region 422. The functional die region 412 and functional die region 422 are both illustrated in FIG. 6, as partial functional overlap regions but there are no areas with functional dies in both of the stacked wafers 410, 420 that align over one another. A defective overlap region 606 is further shown where defective regions 414 and 424 overlap.

As noted above, it is desirable to maximize functional overlap region areas in a stacked wafer arrangement. In one example, wafers, such as first wafer 410, second wafer 420 and third wafer 430 are tested at the wafer stage to determine a map of defective die regions and functional die regions as described. the maps record a defect distribution across the wafers. The maps of wafers 410, 420, 430 are then used to select and align wafers based on the wafer level maps to improve yield within aligned die stacks. For example, as shown in FIGS. 5 and 6, in a two wafer stack, the arrangement of FIG. 5 stacking the first wafer with the third wafer 430 results in a higher functional overlap region 502 compared to the stack configuration of FIG. 6, which results in no functional overlap region.

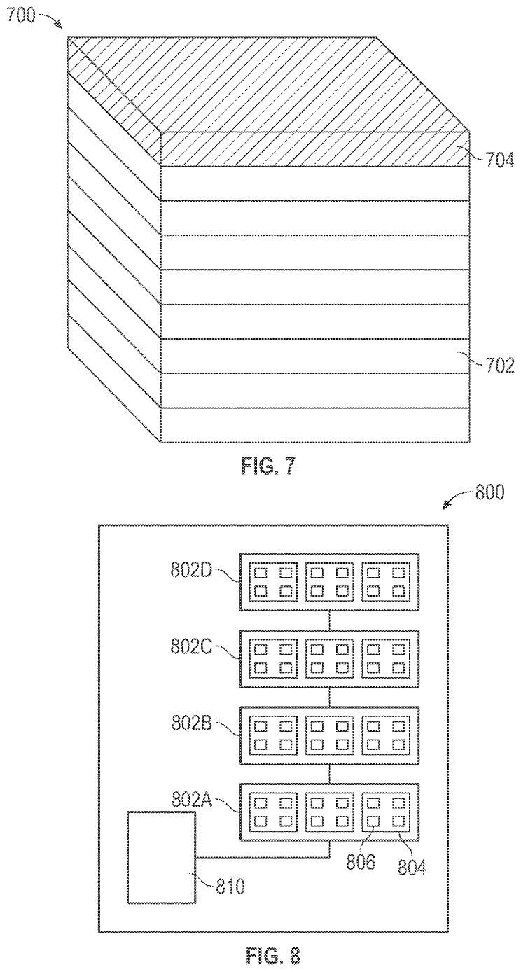

FIG. 7 shows a stack 700 of memory dies 702 formed using methods as described. FIG. 7 includes at least one spare memory die 704 within the stack 700 of memory dies 702. FIG. 8 shows a block diagram of a memory device 800. The memory device 800 includes a stack of memory dies 802A-802D. A memory controller circuit 810 is shown with the stack of memory dies 802A-802D.

Each memory die includes a plurality of memory banks 804. Within each bank 804, are a number of memory channels 806. As such, each memory die 802 can be divided into a number of memory die sub-portions. In the example shown, the banks 804 are sub portions with respect to the die 802, and the channels 806 are sub-portions with respect to each bank 804.

In one example, the spare memory die 704 shown in FIG. 7 includes a number of sub-potions such as memory banks 804 and channels 806. In one example, the memory controller circuit 810 is configured to allocate at least one memory die sub-portion to make up for a defective portion of one of the memory dies 702 in the stack 700. In one example, the memory controller circuit 810 is included within one of the memory dies 702 in the stack 700. In one example, the memory controller circuit 810 is included within a logic die in the stack 700. In one example, the memory controller circuit 810 is included within one or more of the memory dies 702 in the stack.

By including a spare memory die 704 in the stack 700, if a portion of one or more dies 702 in the stack is defective, the defective portion can be compensated for, using all or a portion of the spare memory die 704. The ability to allocate one or more sub-portions of the spare memory die 704 allows more granularity in compensating for small regions of a memory die 702 that may be defective.

When applied to mapping of defective portions of memory wafers as discussed above, the ability to map and compensate with more granularity provides increased flexibility to increase yield in a memory die stack. Instead of mapping whole dies that may be defective, sub-portions of dies may be mapped. Later in manufacturing, when assembled as memory die stacks such as stack 700, the spare die may then be utilized to compensate for defective portions that may exist in one or more of the memory dies 702.

In one example the memory controller circuit 810 is configured to allocate at least one memory die sub-portion at manufacture from the spare memory die 704. In one example the memory controller circuit 810 is configured to allocate at least one memory die sub-portion from the spare memory die 704 dynamically during operation. Although one spare memory die 704 is used as an example, multiple spare memory dies can also be used in a stack depending on the amount of spare memory capacity is needed.

In one example, the stack 700 includes 8 memory dies. In one example 8 memory dies defines a capacity number of dies in a die stack. For example, an 8 die stack of 16 gigabyte dies has a capacity of 128 gigabytes. In one example, a spare die 704 is included and indicates excess capacity over the advertised capacity of 128 gigabytes. In this example, a memory device with 8 normal dies and one spare die provides a capacity of 128 gigabytes with an option of the spare die 704 to compensate for any defects. in the normal 8 dies. Although 8 dies and one spare die are used as an example other numbers of dies in a die stack are also within the scope of the invention.

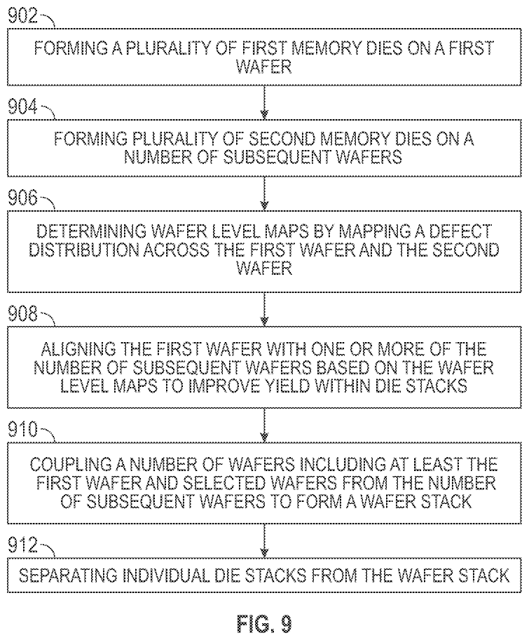

FIG. 9 shows a flow diagram of a method of manufacture according to one example. In operation 902, a plurality of first memory dies are formed on a first wafer. In operation 904, a plurality of second memory dies are formed on a number of subsequent wafers. In operation 906, wafer level maps are determined by mapping a defect distribution across the first wafer and the second wafer. In operation 908, the first wafer is aligned with one or more of the number of subsequent wafers based on the wafer level maps to improve yield within die stacks. In operation 910 a number of wafers including at least the first wafer and selected wafers from the number of subsequent wafers are coupled to form a wafer stack, and in operation 912, individual die stacks are separated from the wafer stack.

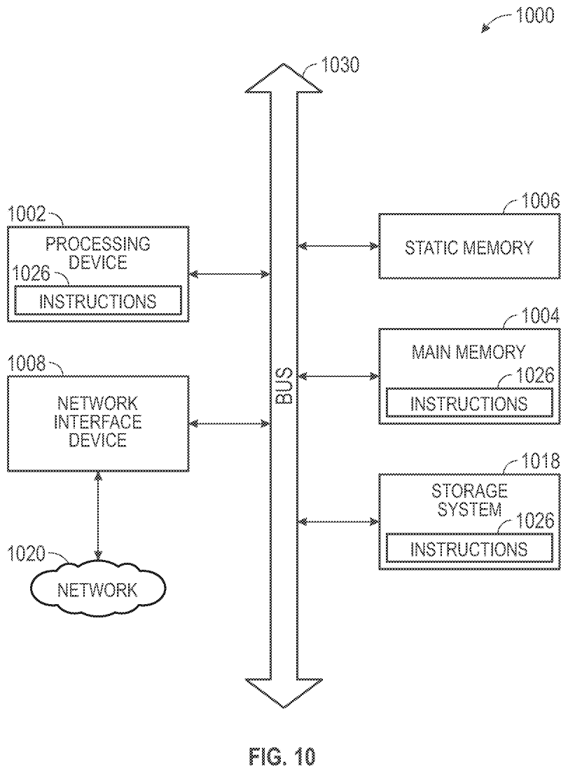

FIG. 10 illustrates a block diagram of an example machine (e.g., a host system) 600 which may include one or more dies, die stacks, memory devices and/or memory systems as described above. As discussed above, machine 1000 may benefit from enhanced memory performance from use of one or more of the described transistor structures and/or memory systems, facilitating improved performance of machine 1000 (as for many such machines or systems, efficient reading and writing of memory can facilitate improved performance of a processor or other components that machine, as described further below.

In alternative embodiments, the machine 1000 may operate as a standalone device or may be connected (e.g., networked) to other machines. In a networked deployment, the machine 1000 may operate in the capacity of a server machine, a client machine, or both in server-client network environments. In an example, the machine 1000 may act as a peer machine in peer-to-peer (P2P) (or other distributed) network environment. The machine 1000 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 1000 may include a processing device 1002 (e.g., a hardware processor, a central processing unit (CPU), a graphics processing unit (GPU), a hardware processor core, or any combination thereof, etc.), a main memory 1004 (e.g., read-only memory (ROM), dynamic random-access memory (DRAM) such as synchronous DRAM (SDRAM) or Rambus DRAM (RDRAM), etc.), a static memory 1006 (e.g., static random-access memory (SRAM), etc.), and a storage system 1018, some or all of which may communicate with each other via a communication interface (e.g., a bus) 1030. In one example, the main memory 1004 includes one or more memory devices as described in examples above.

The processing device 1002 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 1002 can also be one or more special-purpose processing devices such as an application specific integrated circuit (ASIC), a field programmable gate array (FPGA), a digital signal processor (DSP), network processor, or the like. The processing device 1002 can be configured to execute instructions 1026 for performing the operations and steps discussed herein. The computer system 1000 can further include a network interface device 1008 to communicate over a network 1020.

The storage system 1018 can include a machine-readable storage medium (also known as a computer-readable medium) on which is stored one or more sets of instructions 1026 or software embodying any one or more of the methodologies or functions described herein. The instructions 1026 can also reside, completely or at least partially, within the main memory 1004 or within the processing device 1002 during execution thereof by the computer system 1000, the main memory 1004 and the processing device 1002 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 1000 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 1000 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 1026 (e.g., software, programs, an operating system (OS), etc.) or other data are stored on the storage system 1018 can be accessed by the main memory 1004 for use by the processing device 1002. The main memory 1004 (e.g., DRAM) is typically fast, but volatile, and thus a different type of storage than the storage system 1018 (e.g., an SSD), which is suitable for long-term storage, including while in an “off” condition. The instructions 1026 or data in use by a user or the machine 1000 are typically loaded in the main memory 1004 for use by the processing device 1002. When the main memory 1004 is full, virtual space from the storage system 1018 can be allocated to supplement the main memory 1004; however, because the storage system 1018 device is typically slower than the main memory 1004, and write speeds are typically at least twice as slow as read speeds, use of virtual memory can greatly reduce user experience due to storage system latency (in contrast to the main memory 1004, e.g., DRAM). Further, use of the storage system 1018 for virtual memory can greatly reduce the usable lifespan of the storage system 1018.

The instructions 1026 may further be transmitted or received over a network 1020 using a transmission medium via the network interface device 1008 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 1008 may include one or more physical jacks (e.g., Ethernet, coaxial, or phone jacks) or one or more antennas to connect to the network 1020. In an example, the network interface device 1008 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 1000, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

To better illustrate the method and apparatuses disclosed herein, a non-limiting list of embodiments is provided here:

An example of subject matter (e.g., a method of manufacturing a memory device) may comprise forming a plurality of first memory dies on a first wafer, forming plurality of second memory dies on a number of subsequent wafers, determining wafer level maps by mapping a defect distribution across the first wafer and the number of subsequent wafers, aligning the first wafer with one or more of the number of subsequent wafers based on the wafer level maps to improve yield within die stacks, coupling a number of wafers including at least the first wafer and selected wafers from the number of subsequent wafers to form a wafer stack, and separating individual die stacks from the wafer stack.

In an example, which may be combined with any one or more examples described herein, the subject matter may optionally comprise determining die level maps by mapping a defect distribution within sub-die portions of individual dies of the plurality of first memory dies and the plurality of second memory dies while still in the first wafer and the number of subsequent wafers and aligning the first wafer with one or more of the number of subsequent wafers based on the die level maps to improve yield within aligned die stacks.

In an example, which may be combined with any one or more examples described herein, coupling a number of wafers to form a wafer stack optionally includes coupling eight wafers to form a wafer stack.

In an example, which may be combined with any one or more examples described herein, a capacity number of wafers optionally includes a number of wafers needed to provide a memory amount in the die stacks and coupling a number of wafers to form a wafer stack optionally includes coupling at least one spare wafer with the capacity number of wafers to allow for excess memory capacity over the memory amount to make up for defective memory portions in the die stacks.

In an example, which may be combined with any one or more examples described herein, the subject matter may optionally comprise forming allocation circuitry to utilize a portion of the at least one spare wafer.

In an example, which may be combined with any one or more examples described herein, forming allocation circuitry to utilize the portion of the at least one spare wafer optionally includes forming allocation circuitry to utilize a sub-portion of the at least one spare wafer.

An example of subject matter (e.g., a semiconductor memory device) may comprise a stack of memory dies, at least one spare memory die within the stack of memory dies, the at least one spare memory die subdivided into a number of memory die sub-portions, and a memory controller circuit stacked with the stack of memory dies, wherein the memory controller circuit is optionally configured to allocate at least one memory die sub-portion to make up for a defective portion of one memory die in the stack of memory dies.

In an example, which may be combined with any one or more examples described herein, the memory controller circuit is optionally included in at least one memory die in the stack of memory dies.

In an example, which may be combined with any one or more examples described herein, the memory controller circuit is optionally included in a separate controller die stacked with the stack of memory dies.

In an example, which may be combined with any one or more examples described herein, the stack of memory dies optionally includes eight memory dies and at least one spare memory die.

In an example, which may be combined with any one or more examples described herein, the memory controller circuit is optionally configured to allocate at least one memory die sub-portion at manufacture.

In an example, which may be combined with any one or more examples described herein, the memory controller circuit is optionally configured to allocate at least one memory die sub-portion dynamically during operation.

In an example, which may be combined with any one or more examples described herein, the memory die sub-portion optionally includes a die channel.

In an example, which may be combined with any one or more examples described herein, the memory die sub-portion optionally includes a die bank.

An example of subject matter (e.g., an electronic device) may comprise one or more processors and a memory device coupled to the one or more processors, the memory device including a stack of memory dies, at least one spare memory die within the stack of memory dies, the at least one spare memory die subdivided into a number of memory die sub-portions, and a memory controller circuit stacked with the stack of memory dies, wherein the memory controller circuit is optionally configured to allocate at least one memory die sub-portion to make up for a defective portion of one memory die in the stack of memory dies.

In an example, which may be combined with any one or more examples described herein, the subject matter may optionally comprise one or more antennae configured for wireless communication.

In an example, which may be combined with any one or more examples described herein, the stack of memory dies optionally includes a stack of DRAM dies.

In an example, which may be combined with any one or more examples described herein, the memory controller circuit is optionally configured to allocate at least one memory die sub-portion at manufacture.

In an example, which may be combined with any one or more examples described herein, the memory controller circuit is optionally configured to allocate at least one memory die sub-portion dynamically during operation.

In an example, a system, method, or apparatus may optionally combine any portion or combination of any portion of any one or more of the examples described herein, may optionally combine any portion or combination of any portion of any one or more of the examples described herein to comprise “means for” performing any portion of any one or more of the functions, operations, or methods of the examples described herein, or at least one “non-transitory machine-readable medium” including instructions that, when performed by a machine, cause the machine to perform any portion of any one or more of the functions or methods of the examples described herein.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A method of manufacturing a memory device, comprising:
forming a plurality of first memory dies on a first wafer;
forming plurality of second memory dies on a number of subsequent wafers;
determining wafer level maps by mapping a defect distribution across the first wafer and the number of subsequent wafers;
aligning the first wafer with one or more of the number of subsequent wafers based on the wafer level maps to improve yield within die stacks;
coupling a number of wafers including at least the first wafer and selected wafers from the number of subsequent wafers to form a wafer stack; and
separating individual die stacks from the wafer stack.

2. The method of claim 1, further including determining die level maps by mapping a defect distribution within sub-die portions of individual dies of the plurality of first memory dies and the plurality of second memory dies while still in the first wafer and the number of subsequent wafers; and
aligning the first wafer with one or more of the number of subsequent wafers based on the die level maps to improve yield within aligned die stacks.

3. The method of claim 1, wherein coupling a number of wafers to form a wafer stack includes coupling eight wafers to form a wafer stack.

4. The method of claim 1, wherein a capacity number of wafers includes a number of wafers needed to provide a memory amount in the die stacks; and
wherein coupling a number of wafers to form a wafer stack includes coupling at least one spare wafer with the capacity number of wafers to allow for excess memory capacity over the memory amount to make up for defective memory portions in the die stacks.

5. The method of claim 4, further including forming allocation circuitry to utilize a portion of the at least one spare wafer.

6. The method of claim 5, wherein forming allocation circuitry to utilize the portion of the at least one spare wafer includes forming allocation circuitry to utilize a sub-portion of the at least one spare wafer.

7. A semiconductor memory device, comprising;
a stack of memory dies;
at least one spare memory die within the stack of memory dies, the at least one spare memory die subdivided into a number of memory die sub-portions; and
a memory controller circuit stacked with the stack of memory dies;
wherein the memory controller circuit is configured to allocate at least one memory die sub-portion to make up for a defective portion of one memory die in the stack of memory dies.

8. The semiconductor memory device of claim 7, wherein the memory controller circuit is included in at least one memory die in the stack of memory dies.

9. The semiconductor memory device of claim 7, wherein the memory controller circuit is included in a separate controller die stacked with the stack of memory dies.

10. The semiconductor memory device of claim 7, wherein the stack of memory dies includes eight memory dies and at least one spare memory die.

11. The semiconductor memory device of claim 7, wherein the memory controller circuit is configured to allocate at least one memory die sub-portion at manufacture.

12. The semiconductor memory device of claim 7, wherein the memory controller circuit is configured to allocate at least one memory die sub-portion dynamically during operation.

13. The semiconductor memory device of claim 7, wherein the memory die sub-portion includes a die channel.

14. The semiconductor memory device of claim 7, wherein the memory die sub-portion includes a die bank.

15. An electronic device, comprising;
one or more processors;
a memory device coupled to the one or more processors, the memory device including:
a stack of memory dies;
at least one spare memory die within the stack of memory dies, the at least one spare memory die subdivided into a number of memory die sub-portions; and
a memory controller circuit stacked with the stack of memory dies;
wherein the memory controller circuit is configured to allocate at least one memory die sub-portion to make up for a defective portion of one memory die in the stack of memory dies.

16. The electronic device of claim 15, further including one or more antennae configured for wireless communication.

17. The electronic device of claim 15, wherein the stack of memory dies includes a stack of DRAM dies.

18. The electronic device of claim 15, wherein the memory controller circuit is configured to allocate at least one memory die sub-portion at manufacture.

19. The electronic device of claim 15, wherein the memory controller circuit is configured to allocate at least one memory die sub-portion at dynamically during operation.
